(19) United States
(12) Patent Application Publication
(10) Pub. No.: US 2006/0132248 A1
(43) Pub. Date: Jun. 22, 2006

(54) Bulk acoustic wave crystal controlled clock with surface acoustic wave filter multiplier

(75) Inventors: Jerry A. Lichter, Burlington, WI (US); Randal D. Kohloff, New Berlin, WI (US)

Correspondence Address: GODFREY & KAHN S.C., 780 NORTH WATER STREET, MILWAUKEE, WI, 53202, US

(73) Assignee: NEL Frequency Controls, Inc.

(21) Appl. No.: 11/100,705

(22) Filed: Apr. 7, 2005

Related U.S. Application Data
(60) Provisional application No. 60/636,476, filed on Dec. 16, 2004.

(51) Int. Cl. H03B 5/32

(52) U.S. Cl. 331/107 A

(57) ABSTRACT

An oscillator circuit comprising a bulk acoustic wave (BAW) crystal clock oscillator that generates a high stability, tight frequency tolerance signal. This signal being multiplied by a surface acoustic wave (SAW) filter multiplier that filters out all signals except the desired harmonic of the BAW oscillator signal resulting in a multiple of the BAW oscillator frequency with the frequency stability verses temperature of the original BAW oscillator signal. The output of the SAW filter is coupled to an amplifier/buffer to restore the SAW filter output signal to the desired signal level and/or waveform.

### CROSS-REFERENCE TO RELATED APPLICATIONS

This application is based on and claims the benefit of U.S. Provisional Application No. 60/636,476, filed Dec. 16, 2004.

### BACKGROUND OF THE INVENTION

The present invention relates generally to crystal controlled oscillators. The present invention relates specifically to a bulk acoustic wave (BAW) crystal controlled clock oscillator with a surface acoustic wave (SAW) filter multiplier or other high quality factor (Q) filter multiplier for providing a high stability clock reference signal.

Piezoelectric devices for use as oscillators and filters are well known in the art. In particular, electronic circuitry for crystal oscillators using either a BAW crystal or a SAW crystal is also well known in the art. There are many manufacturers that manufacture crystal oscillators using BAW crystal and SAW crystal technologies. Examples of some of these manufacturers include The Connor-Winfield Corporation, CTS Corporation, NEL Frequency Controls, Inc., and Vectron International.

Typically, BAW crystals and SAW crystals are used as a reference clock when accuracy is most critical in high frequency applications where low jitter and low phase noise is required. It is widely accepted that of all forms of commercially available oscillators, piezoelectric crystals provide the only acceptable performance for high end applications that require a high Q factor, low phase noise and low jitter. However, these solutions have frequency and affordability limitations.

The most common crystals found commercially are BAW crystals. They vary in terms of their oscillation modes, overtone or fundamental, and their fabrication. However, BAW crystals present two main limitations: affordability and available frequency. A BAW crystal is limited to approximately 300 MHz due to the manufacturing capability of the quartz resonator. Certain applications require frequencies higher then the traditional BAW can reasonably operate.

SAW crystals tend to be less common in frequency reference applications given their wider temperature tolerance, and higher tooling costs for a given frequency. This makes SAW based clock references inadequate for most high accuracy applications. However, SAW based technologies are most suitable to reach higher frequency ranges. As a result, SAW based products are most typically used as voltage controlled crystal oscillators (VCXOs) in phase locked loop (PLL) designs or as filters. In addition to the poor temperature tolerance of SAW devices, the limited number of SAW crystal producers for reference clock applications further contributes to the dominance of BAW crystals in the field.

An example of a SAW based oscillator is shown in U.S. Pat. No. 4,871,984 to Laton et al. This SAW based oscillator is limited to the frequency verses temperature characteristics of the SAW resonator, which is typically worse than a BAW based oscillator. SAW resonators generally have a frequency verses temperature characteristic of a downward parabolic curve which provides approximately 40 ppm or more of downward shift from the turnover point within a 0° C. to 70° C. temperature window. The SAW resonator frequency verses temperature characteristic generally degrades even further with variations in turnover temperature, temperature constants and calibration of the crystal. The SAW oscillator is limited to loose tolerance applications since the frequency verses temperature characteristic of a SAW oscillator is significantly worse then a BAW oscillator. A frequency tolerance of less then ±100 ppm from 0° C. to 70° C. is not achievable from a SAW based oscillator due to the frequency verses temperature characteristic of the SAW oscillator.

Multiplying the output of a source oscillator with a frequency multiplier circuit is also well known in the art. The multiplying is generally done via a common PLL synthesizer circuit that is well known and documented in prior art textbooks. Another common multiplier method is to use a non-linear device to filter out a second or even harmonic as the output signal.

An example of a PLL based frequency multiplier circuit is shown in U.S. Pat. No. 6,456,143 to Musumoto et al. Multiplying the BAW oscillator output signal by using a PLL circuit causes more jitter and phase noise at the output signal than some critical applications can tolerate.

Using a non-linear device, such as a transistor multiplier, to create the second harmonic and then filtering that signal produces less harmonic content and thus is more difficult to amplify to the levels needed to produce a usable output signal. An example of the use of a transistor multiplier circuit is disclosed in a paper entitled “622.08 MHz SMD-VCXO with filter,” and presented at the 2001 IEEE International Frequency Control Symposium and PDA Exhibition by Sato et al. of Nihon Dempa Kogyo Co., Ltd in Japan. This prior art circuit uses a crystal oscillator with a filter to obtain a 4th harmonic. The prior art circuit uses the non-linear characteristics of a transistor filter multiplier to obtain an even harmonic (the 4th harmonic in the case shown in the presented paper). This prior art circuit is limited in the ability to get enough 4th harmonic to amplify for a reliable output signal. In addition, the filter being implemented has a lower Q than a SAW filter which would cause higher noise levels in the output signal.

The oscillator circuit of the present invention was developed for applications that require frequencies higher then the traditional BAW crystal oscillator can reasonably operate and applications that require very tight frequency tolerances, and very low jitter and/or phase noise.

### SUMMARY OF THE INVENTION

The present invention provides a high stability clock reference signal based on a very stable BAW crystal clock oscillator, generally using an AT or SC cut crystal, and multiplying the output from the BAW crystal clock oscillator with a SAW filter or other high Q factor filter multiplier. This approach allows for a source oscillator that has the frequency stability over temperature of the BAW oscillator, being generally well under ±10 ppm from 0° C. to 70° C. for an AT cut crystal, and jitter and/or phase noise comparable to the BAW oscillator, but in a frequency range not normally attainable by the BAW oscillator. The SAW filter is used to select an odd or even harmonic that is present in the generation of source signal of the BAW oscillator. The SAW filter center frequency is selected to be the BAW output frequency times the harmonic order that is desired. This harmonic output from the SAW filter has the frequency stability of the original BAW oscillator output, but the output frequency of the BAW oscillator times the harmonic multiplier selected by the filter.

The present invention preferably includes a BAW crystal clock oscillator that generates a high stability, tight frequency tolerance signal and a SAW filter multiplier that filters out all signals except the desired harmonic of the BAW oscillator signal resulting in a multiple of the BAW oscillator frequency with the frequency stability verses temperature of the original BAW oscillator signal. An amplifier/buffer is preferably included at the output of the SAW filter to restore the SAW filter output signal to the desired signal level. Any digital or high harmonic content BAW crystal clock oscillator can be used for the reference source such as a fixed crystal oscillator (XO), a voltage controlled crystal oscillator (VCXO), a temperature compensated crystal oscillator (TCXO), or an oven controlled crystal oscillator (OCXO). The crystal is preferably an AT or SC cut crystal.

In another embodiment of the BAW oscillator and filter multiplier circuit of the present invention, a thin film bulk acoustic resonator (FBAR) filter is used instead of the SAW filter. The FBAR filter is another high Q filter multiplier.

Various other features, objects, and advantages of the invention will be made apparent to those skilled in the art from the following detailed description, claims, and accompanying drawings.

### BRIEF DESCRIPTION OF THE DRAWINGS

FIG. 1 is a block diagram of an embodiment of a BAW oscillator and SAW filter multiplier circuit of the present invention;

FIG. 2 is a block diagram of an embodiment of a BAW oscillator and FBAR filter multiplier circuit of the present invention;

FIG. 3 is a schematic diagram of the BAW oscillator and filter multiplier circuits of FIGS. 1 and 2;

FIG. 4 is a schematic diagram of an embodiment of a BAW oscillator circuit of the present invention; and

FIG. 5 is a schematic diagram of an embodiment of the BAW oscillator and filter multiplier circuit of the present invention incorporating the BAW oscillator circuit of FIG. 4.

### DETAILED DESCRIPTION OF THE INVENTION

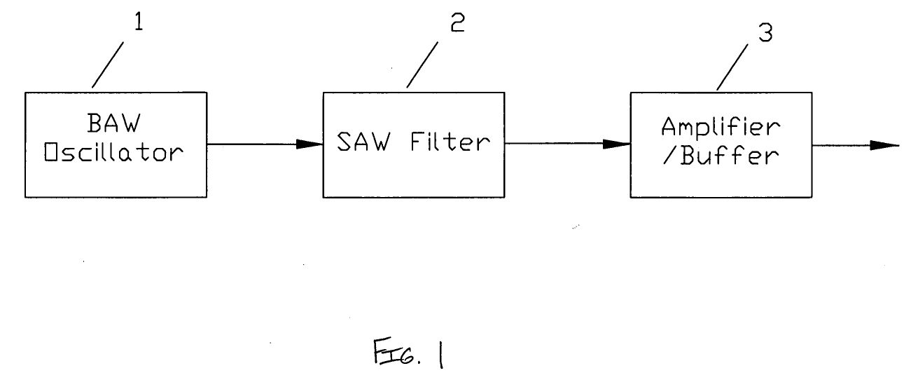

Referring now to the drawings, FIG. 1 is a block diagram of an embodiment of a BAW oscillator and SAW filter multiplier circuit of the present invention. The oscillator circuit preferably comprises a BAW crystal clock oscillator 1 that provides a high stability clock reference signal, a SAW filter multiplier 2 that provides a harmonic output that is a desired harmonic multiple of the BAW oscillator frequency, and an amplifier buffer 3 that amplifies the SAW filter output signal to the desired signal level.

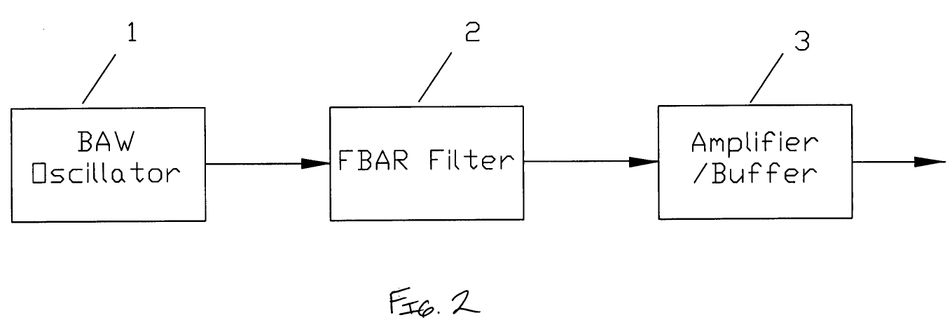

FIG. 2 is another block diagram of an embodiment of a BAW oscillator and FBAR filter multiplier circuit of the present invention. The oscillator circuit preferably comprises a BAW crystal clock oscillator 1 that provides a high stability clock reference signal, a FBAR filter multiplier 2 that provides a harmonic output that is a desired harmonic multiple of the BAW oscillator frequency, and an amplifier buffer 3 that amplifies the FBAR filter output signal to the desired signal level.

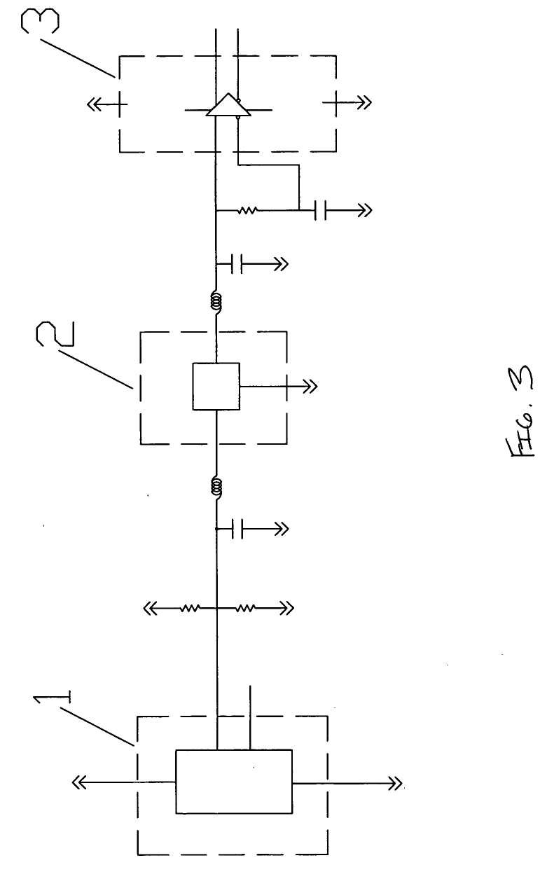

FIG. 3 is a schematic diagram of the BAW oscillator and filter multiplier circuits of FIGS. 1 and 2. The BAW oscillator 1 preferably comprises a bulk acoustic wave resonator in a crystal oscillator circuit. Many crystal oscillator circuits are available for use and can be any overtone order of the resonator. The crystal oscillator can be a fixed crystal oscillator (XO), a voltage controlled crystal oscillator (VCXO), a temperature compensated crystal oscillator (TCXO), or an oven controlled crystal oscillator (OCXO). The crystal is preferably an AT or SC cut crystal. A square wave or sine wave output from the crystal oscillator is desired to produce a plurality of odd or even harmonics for the filter. In a preferred embodiment, the output of the crystal oscillator is a square wave used to produce a plurality of odd harmonics for the filter.

The present invention utilizes the odd harmonics by filtering from a digital signal, being close to a square wave. This square wave has a large amount of odd harmonic content which makes it easier to filter and amplify for multiplication. The circuit of the present invention provides better isolation between stages making the design less complicated at higher frequencies. The present invention also preferably uses a SAW or FBAR filter instead of using an LC filter or other low Q filter as used in the prior art. The quality factor Q of the SAW or FBAR filter is higher giving the circuit of the present invention higher amplitude levels. Higher amplitude levels are desirable prior to amplifying to reduce the noise levels being amplified.

The filter 2 preferably comprises a SAW filter or a FBAR filter and a plurality of discrete matching components (resistors, capacitors and inductors) necessary to accomplish the impedance matching of the filter 2 to the rest of the circuit. The filter 2 bandwidth over the operating conditions of the entire circuit must contain the center frequency plus the frequency tolerance of the BAW oscillator 1 harmonics over the operating conditions. The filter 2 bandwidth must not be too wide so it allows the unwanted harmonics of the BAW oscillator 1 to also pass through the filter 2. The filter 2 must have a frequency response characteristic to remove all the unwanted frequencies of the BAW oscillator 1 and select only the desired harmonic multiple of the BAW oscillator's fundamental frequency.

The circuit of the present invention also preferably includes an amplifier and/or buffer 3 in order to obtain the desired signal strength or wave shape required for the circuit that this design is intended to drive. The amplifier/buffer 3 is preferably an analog amplifier for a sine wave output requirement or a digital buffer required for driving a digital circuit such as a CMOS or PECL circuit. In the example shown in FIG. 3, the amplifier/buffer 3 is an ECL line receiver, such as a 100EL16-5V ECL differential receiver.

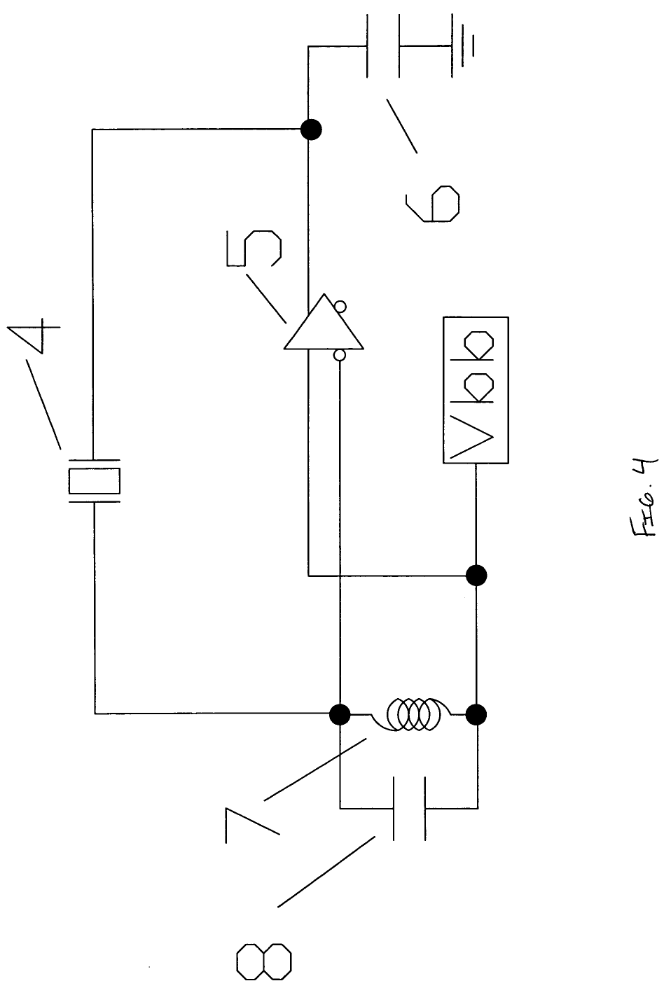

One example of an acceptable circuit for the BAW oscillator 1 is shown in FIG. 4. FIG. 4 is a schematic diagram of an embodiment of a BAW oscillator circuit of the present invention. The oscillator circuit of this embodiment preferably comprises a gate oscillator having an inverting gate or inverter 5, a capacitor 6 and 8 on each side of the inverter 5, an inductor 7 on the input side of the inverter 5, and a crystal 4 in the feedback path of the inverter 5. The inductor 7 is used to select the desired overtone order of the crystal 4 and would not be included for a fundamental mode crystal. The gate oscillator 5, such as a 10H116 differential line receiver as shown in FIG. 4, supplies the amplifier stage and Vbb bias for the circuit, capacitors 6 and 8 supply additional phase shift for the circuit to allow oscillation with the crystal 4. The inductor 7 is used to create an inductor capacitor tank circuit with capacitor 8 to select the overtone order of the crystal 4 being used in the circuit.

The example shown in FIG. 4 uses an ECL gate which does not require a feedback resistor to provide the bias and gain adjust necessary for a TTL or CMOS inverting gate. If a TTL or CMOS inverting gate were used, a feedback resistor would be required in the feedback path of the inverting gate.

The stability of a non-compensated BAW AT cut resonator is much tighter than a SAW resonator. The BAW AT cut resonator frequency drift with temperature can be as low as ±2 ppm from 0° C. to 50° C. (or as indicated earlier, less then ±10 ppm from 0° C. to 70° C.). As mentioned above, other controlled or compensated crystal oscillators can be used such as a VCXO for small frequency movement, a TCXO for extra stability, or an OCXO for very tight stability. The output stability of the overall circuitry will be the stability of this reference oscillator.

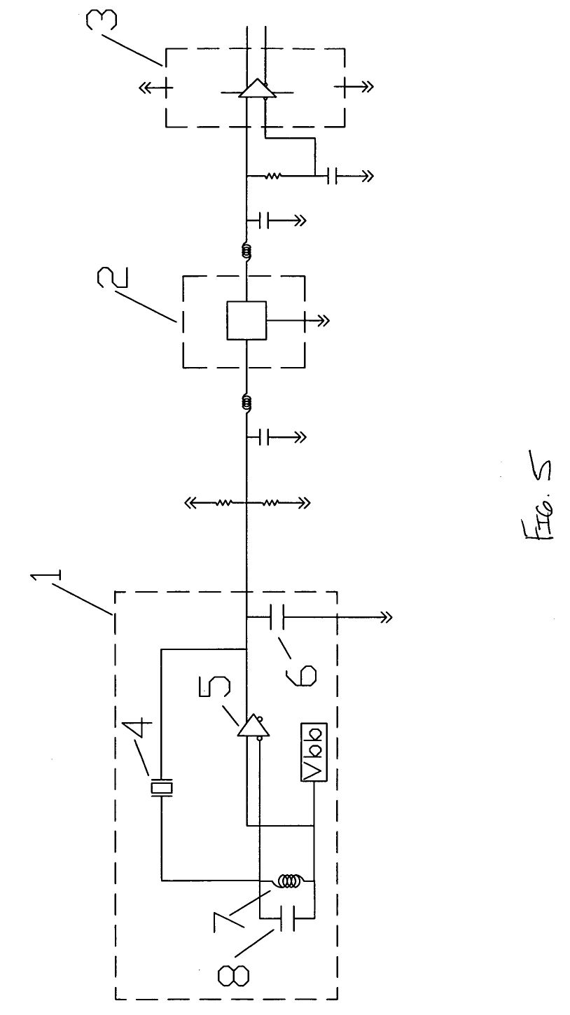

FIG. 5 is a schematic diagram of an embodiment of the BAW oscillator and filter multiplier circuit of the present invention incorporating the BAW oscillator circuit of FIG. 4. The BAW oscillator 1 is preferably a 177 MHz, AT cut BAW crystal oscillator created via a standard gate oscillator circuit. An AT cut third overtone crystal 4 provides the basic frequency reference for the BAW oscillator 1. The output of the gate oscillator circuit 1 is preferably filtered with a SAW filter 2 having a center frequency of 531 MHz (three (3) times the fundamental 177 MHz frequency of the oscillator). The SAW filter 2 bandwidth is preferably about 1 MHz, which is wide enough to contain the AT cut crystal 4 tolerance at the third harmonic selected and the drift of the SAW filter 2. A simple PECL receiver buffer, such as a 100EL16 ECL line receiver 3, amplifies the output of the SAW filter 2 and provides the PECL signal level needed for a PECL oscillator. The SAW filter 2 is preferably a 533.33 MHz SMD, part number TB0264A, manufactured by TAI-SAW Technology Co., Ltd. of Taiwan, having a center frequency of 533.33 MHz. As mentioned previously, in another embodiment of the present invention, a FBAR filter 2 may be used in place of the SAW filter 2.

While the invention has been described with reference to preferred embodiments, it is to be understood that the invention is not intended to be limited to the specific embodiments set forth above. Thus, it is recognized that those skilled in the art will appreciate that certain substitutions, alterations, modifications, and omissions may be made without departing from the spirit or intent of the invention. Accordingly, the foregoing description is meant to be exemplary only, the invention is to be taken as including all reasonable equivalents to the subject matter of the invention, and should not limit the scope of the invention as set forth in the following claims.

What is claimed is:

1. An oscillator circuit comprising:
a bulk acoustic wave (BAW) crystal oscillator;
a filter coupled to the output of the BAW crystal oscillator; and
an amplifier coupled to the output of the filter for amplifying the filter output to a desired signal level.

2. The oscillator circuit of claim 1, wherein the BAW crystal oscillator utilizes an AT cut crystal.

3. The oscillator circuit of claim 1, wherein the BAW crystal oscillator utilizes a SC cut crystal.

4. The oscillator circuit of claim 1, wherein the BAW crystal oscillator is at least one of a fixed crystal oscillator (XO), a voltage controlled crystal oscillator (VCXO), a temperature compensated crystal oscillator (TCXO), or an oven controlled crystal oscillator (OCXO).

5. The oscillator circuit of claim 1, wherein the filter is a surface acoustic wave (SAW) filter multiplier.

6. The oscillator circuit of claim 1, wherein the filter is a thin film bulk acoustic resonator (FBAR) filter.

7. The oscillator circuit of claim 1, wherein the filter has a center frequency selected to be the BAW crystal oscillator output frequency multiplied by the harmonic order that is desired.

8. The oscillator circuit of claim 1, wherein the amplifier output has the same frequency versus temperature characteristics of the BAW crystal oscillator output.

9. An oscillator circuit comprising:
a bulk acoustic wave (BAW) crystal oscillator;
a filter coupled to the output of the BAW crystal oscillator; and
a buffer coupled to the output of the filter for driving a digital circuit.

10. The oscillator circuit of claim 9, wherein the BAW crystal oscillator utilizes an AT cut crystal.

11. The oscillator circuit of claim 9, wherein the BAW crystal oscillator utilizes a SC cut crystal.

12. The oscillator circuit of claim 9, wherein the BAW crystal oscillator is at least one of a fixed crystal oscillator (XO), a voltage controlled crystal oscillator (VCXO), a temperature compensated crystal oscillator (TCXO), or an oven controlled crystal oscillator (OCXO).

13. The oscillator circuit of claim 9, wherein the filter is a surface acoustic wave (SAW) filter multiplier.

14. The oscillator circuit of claim 9, wherein the filter is a thin film bulk acoustic resonator (FBAR) filter.

15. The oscillator circuit of claim 9, wherein the amplifier output has the same frequency versus temperature characteristics of the BAW crystal oscillator output.

16. The oscillator circuit of claim 9, wherein the filter has a center frequency selected to be the BAW crystal oscillator output frequency multiplied by the harmonic order that is desired.

17. A method for providing a high stability clock reference signal, the method comprising the steps of:
providing a bulk acoustic wave (BAW) crystal oscillator;
multiplying the output of the BAW crystal oscillator with a surface acoustic wave (SAW) filter multiplier;
amplifying or buffering the output of the filter multiplier to a desired signal level and/or waveform.

18. The method of claim 17, wherein the BAW crystal oscillator utilizes an AT cut crystal.

19. The method of claim 17, wherein the BAW crystal oscillator utilizes a SC cut crystal.

20. The method of claim 17, wherein the BAW crystal oscillator is at least one of a fixed crystal oscillator (XO), a voltage controlled crystal oscillator (VCXO), a temperature compensated crystal oscillator (TCXO), or an oven controlled crystal oscillator (OCXO).

21. The method of claim 17, wherein the filter is a thin film bulk acoustic resonator (FBAR) filter.

22. The method of claim 17, wherein the amplifier or buffer output has the same frequency versus temperature characteristics of the BAW crystal oscillator output.

23. The method of claim 17, wherein the filter has a center frequency selected to be the BAW crystal oscillator output frequency multiplied by the harmonic order that is desired.
